(19) United States
(12) Patent Application Publication
(10) Pub. No.: US 2024/0160821 A1
(43) Pub. Date: May 16, 2024

(54) INFORMATION PROCESSING METHOD, INFORMATION PROCESSING APPARATUS, PROGRAM, AND NON-TRANSITORY COMPUTER READABLE MEDIUM STORING PROGRAM

(71) Applicant: RENESAS ELECTRONICS CORPORATION, Tokyo (JP)

(72) Inventor: Yuji HISAMATSU, Tokyo (JP)

(21) Appl. No.: 18/480,077

(22) Filed: Oct. 3, 2023

(30) Foreign Application Priority Data
Nov. 16, 2022 (JP) 2022-183246

(51) Int. Cl. G06F 30/3308; G06F 30/323

(52) U.S. Cl. CPC G06F 30/3308; G06F 30/323

(57) ABSTRACT

Simulation of a semiconductor integrated circuit is appropriately performed. An information processing apparatus is provided, the information processing apparatus including: a first calculator calculating a processing time of each of a plurality of circuit components, based on a first abstraction level model corresponding to each of the circuit components included in a semiconductor integrated circuit; and a second calculator simulating processing of the semiconductor integrated circuit, based on the processing time of each of the circuit components calculated by the first calculator and a second abstraction level model having a higher level of abstraction than a level of the first abstraction level model.

### CROSS-REFERENCE TO RELATED APPLICATION

The disclosure of Japanese Patent Application No. 2022-183246 filed on Nov. 16, 2022, including the specification, drawings and abstract is incorporated herein by reference in its entirety.

### BACKGROUND

The present disclosure relates to, for example, an information processing method of simulating a system having a plurality of components, an information processing apparatus, a program, and a non-transitory computer readable medium storing the program.

There is disclosed technique listed below.
[Patent Document 1] U.S. Unexamined Patent Application Publication No. 2021/0357549

In recent years, the use of model-based design has become active in the development of on-board large-scale integration (LSI) and others based on the concept of software first. With regard to this technique, the Patent Document 1 discloses a technique of switching and using a plurality of simulation models with different levels of abstraction during a simulation operation. When a simulation model with a low level of abstraction is used, the simulation accuracy is improved while the time required for the simulation is increased. Also, when a simulation model with a high level of abstraction is used, the simulation accuracy is reduced while the time required for the simulation is decreased.

### SUMMARY

However, in some cases, in the technique described in the Patent Document 1, it cannot be properly checked whether or not the time required for the processing of a semiconductor integrated circuit satisfies specific conditions (requirement and constraint) while reducing the time required for the simulation. Other problems and novel characteristics will become apparent from the description of the present specification and the accompanying drawings.

In one embodiment, the processing time of the circuit component is calculated based on a low abstraction level model for a circuit component included in a semiconductor integrated circuit, and then, the processing of the semiconductor integrated circuit is simulated based on the processing time and a high abstraction level model.

According to the above-described embodiment, it can be properly checked whether or not the time required for the processing of a semiconductor integrated circuit satisfies specific conditions while reducing the time required for the simulation.

### BRIEF DESCRIPTIONS OF THE DRAWINGS

FIG. 1 is a block diagram showing an example of a configuration of an information processing apparatus according to one embodiment.

FIG. 2 is a block diagram showing an example of a hardware configuration of the information processing apparatus according to one embodiment.

FIG. 3 is a flowchart showing an example of processing of the information processing apparatus according to one embodiment.

FIG. 4 is a block diagram showing an example of a low abstraction level model according to one embodiment.

FIG. 5 is a diagram showing an example of information stored in a characteristic DB according to one embodiment.

FIG. 6 is a block diagram showing an example of a high abstraction level model according to one embodiment.

FIG. 7 is a flowchart showing an example of processing of the information processing apparatus according to one embodiment.

### DETAILED DESCRIPTION

The present disclosure will be described with reference to some exemplary embodiments. It should be understood that these embodiments are described for illustrative purposes only, and are intended to support those skilled in the art to understand and implement the present disclosure without implying any limitations as to the scope of the present disclosure. The disclosure described in the present specification is achieved by various methods other than those described below.

In the following description and claims, unless otherwise defined, all technical and scientific terms used in the present specification have the same meaning as those generally understood by those skilled in the art to which this disclosure pertains.

With reference to the accompanying drawings, embodiments of the present invention will be described below.

### First Embodiment

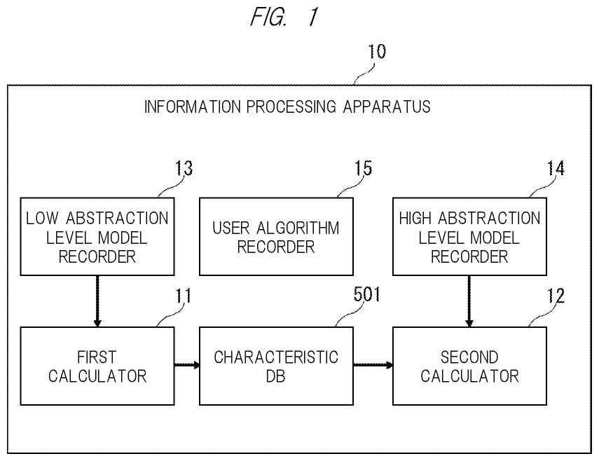

With reference to FIG. 1, a configuration of an information processing apparatus 10 (simulation apparatus) according to the present embodiment will be described. FIG. 1 is a block diagram showing an example of the configuration of the information processing apparatus 10 according to the present embodiment. The information processing apparatus 10 includes a first calculator 11, a second calculator 12, a low abstraction level model recorder 13, a high abstraction level model recorder 14, a user algorithm recorder 15, and a characteristic database (DB) 501. Each of these parts may be achieved by the cooperation of one or more programs installed in the information processing apparatus 10, the processor of the information processing apparatus 10, and hardware such as memory.

The first calculator 11 calculates the processing time for each circuit component, based on an algorithm specified by a user and a first abstraction level model (hereinafter also referred to as a “low abstraction level model” as appropriate) corresponding to each of the plurality of circuit components included in the semiconductor integrated circuit.

The second calculator 12 simulates the processing of the semiconductor integrated circuit, based on an algorithm specified by a user, the processing time of each circuit component calculated by the first calculator 11, and a second abstraction level model (hereinafter also referred to as a “high abstraction level model” as appropriate) with a higher abstraction level than that of the first abstraction level model.

The low abstraction level model recorder 13 records the low abstraction level model. The low abstraction level model may be previously recorded (registered or set) in the low abstraction level model recorder 13 by the user or the like. The high abstraction level model recorder 14 records the high abstraction level model. The high abstraction level model may be previously recorded in the high abstraction level model recorder 14 by the user or the like.

The user algorithm recorder 15 records data (e.g., a program developed by the user) indicating the algorithm specified (developed or designed) by the user who is a developer. The data indicating the algorithm may be previously recorded in the user algorithm recorder 15 by the user or the like. The characteristic DB (database) 501 records the processing time of each circuit component calculated by the first calculator 11.

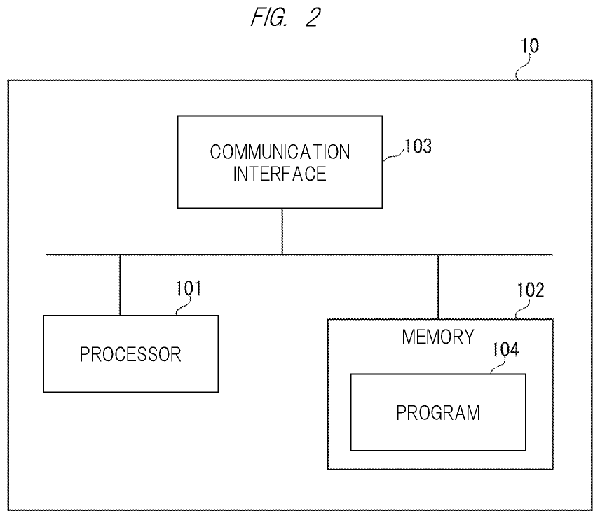

FIG. 2 is a block diagram showing an example of a hardware configuration of the information processing apparatus 10 according to the present embodiment. In the example shown in FIG. 2, the information processing apparatus 10 includes a processor 101, a memory 102, and a communication interface 103. These components may be connected by a bus. The memory 102 stores at least a part of the program 104. The communication interface 103 includes an interface necessary for communication with other network elements.

When the program 104 is executed by the cooperation of the processor 101 and the memory 102, at least a part of the processing of embodiments of the present disclosure is executed by the information processing apparatus 10. The memory 102 may be of any type. The memory 102 may be a non-transitory computer readable storage medium, as a non-limiting example. The memory 102 may also be achieved by any suitable data storage technique, such as a semiconductor-based memory device, magnetic memory device, optical memory device, fixed memory, and removable memory. Although only one memory 102 is illustrated in the information processing apparatus 10, the information processor 10 may include some physically different memory modules. The processor 101 may be of any type. The processor 101 may include one or more of a microprocessor, a digital signal processor (DSP), and a processor based on the multi-core processor architecture as a non-limiting example.

A program includes an instruction group (or software code) used to make the computer perform one or more functions described in the present embodiment when being loaded into a computer. The program may be stored in a non-transitory computer readable medium or a tangible storage medium. The computer readable media or tangible storage media may include, for example, random-access memory (RAM), read-only memory (ROM), flash memory, solid-state drive (SSD), other memory techniques, CD-ROM, digital versatile disc (DVD), Blu-ray (registered trademark) disc, other optical disc storages, magnetic cassette, magnetic tape, magnetic disk storage, and other magnetic storage device, but are not limited thereto. The program may be transmitted on a transitory computer readable medium or communication medium. The transitory computer readable media or communication media include, for example, electrical, optical, acoustic, and other-form propagation signals, but are not limited thereto.

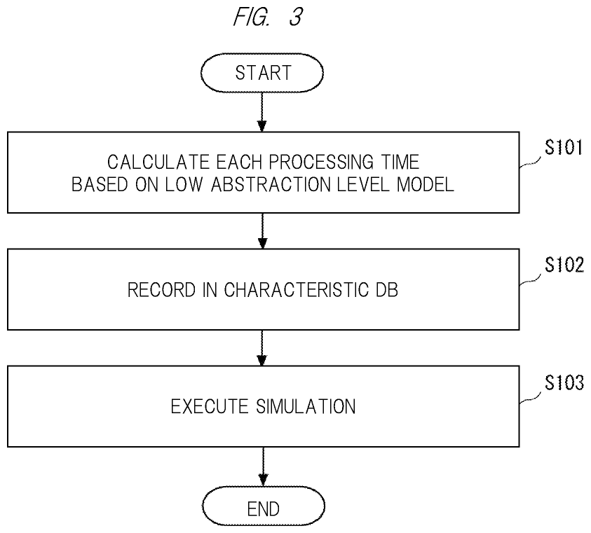

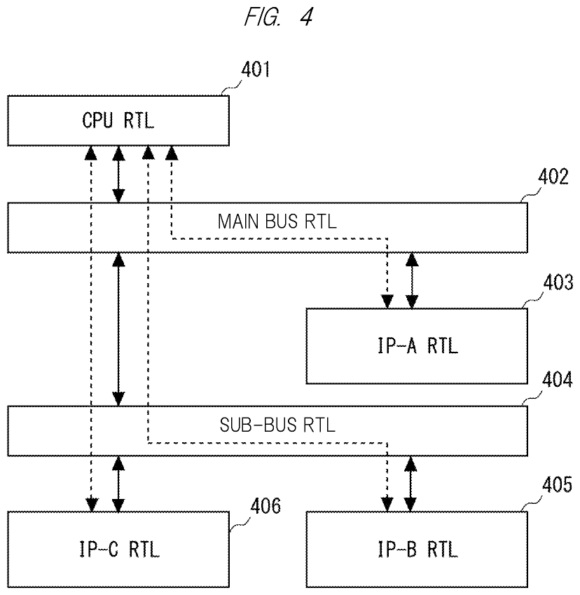

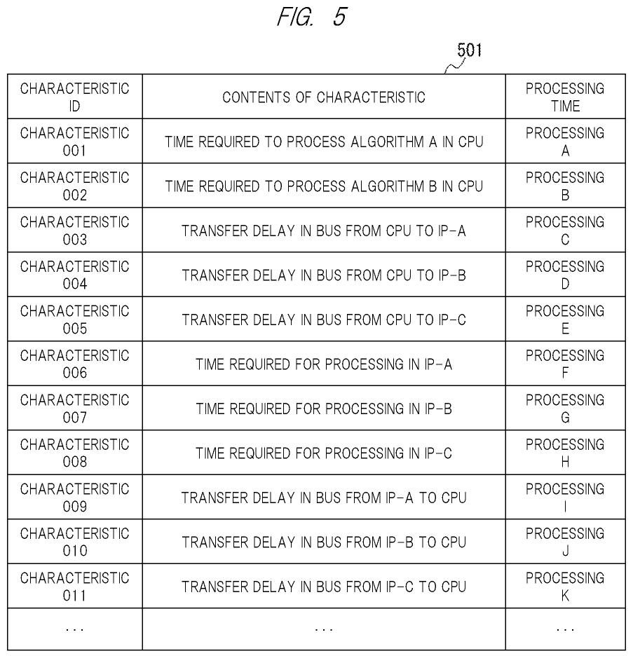

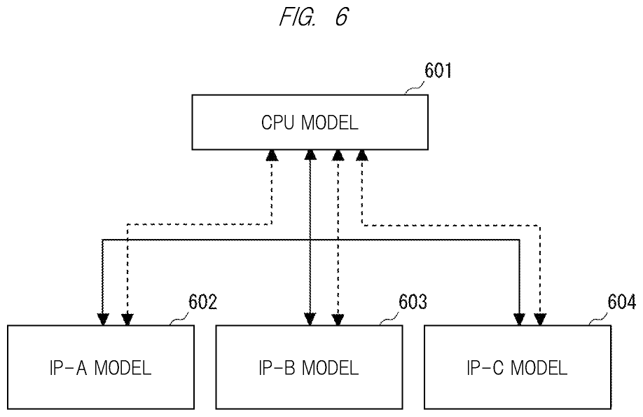

Next, with reference to FIG. 3 to FIG. 6, the processing of the information processing apparatus 10 according to the present embodiment will be described. FIG. 3 is a flowchart showing an example of the processing of the information processing apparatus 10 according to the present embodiment. FIG. 4 is a block diagram showing an example of a low abstraction level model according to the present embodiment. FIG. 5 is a diagram showing an example of information stored in the characteristic DB 501 according to the present embodiment. FIG. 6 is a block diagram showing an example of a high abstraction level model according to the present embodiment. The processing shown in FIG. 3 may be executed in response to, for example, an operation of the information processing apparatus 10 by the user.

In step S101 of FIG. 3, the first calculator 11 calculates the processing time for each circuit component, based on the algorithm specified by the user and the low abstraction level model for each of the plurality of circuit components. Here, the first calculator 11 may use, as the low abstraction level model, circuit data of a register transfer level (RTL) described with a hardware description language (HDL). In this case, the low abstraction level model may have a hierarchical structure of the plurality of circuit components, and the function of each circuit component may be expressed by an HDL (e.g., Verilog HDL or VHDL (VHSIC HDL)).

In the example in FIG. 4, in a semiconductor integrated circuit, a CPU is connected to the main bus, IP (Intellectual Property)-A and a sub-bus are connected to the main bus, and IP-B and IP-C are connected to the sub-bus. Note that IP-A, IP-B, and IP-C may be circuit components based on an IP core (intellectual property core) in which circuit information is collected for each functional block, offered from a circuit-component vendor. When the IP core offered from the vendor is used, the user of the information processing apparatus 10 can improve efficiency of the development. Data 401 to 406 of the RTL of each circuit component may be offered from, for example, the vendor of each circuit component to the user of the information processing apparatus 10 (the circuit component based on the IP core is also referred to simply as an “IP core” as appropriate below).

Then, the first calculator 11 records the calculated processing time of each circuit component into the characteristic DB 501 (step S102). In the example in FIG. 5, the characteristic contents and the processing time are recorded in the characteristic DB501 in association with a characteristic ID. The characteristic ID indicates identification information about the processing contents. The processing contents of each circuit component may include, for example, the time required to process each algorithm in the CPU (time required for processing), the transfer delay in the bus from the CPU to each IP core (time required for transfer), the time required for processing in each IP core, and the transfer delay in the bus from each IP core to the CPU. The processing time is the time required for processing (the required time). The processing time may be a value in units of, for example, milliseconds (ms).

The first calculator 11 calculates the processing time of Algorithm A in the CPU, based on, for example, the data 401 of the RTL of the CPU and Algorithm A recorded in the user algorithm recorder 15. In the example of FIG. 5, “Characteristic 001” showing that the processing time of Algorithm A in the CPU is “Processing Time A” is recorded. The first calculator 11 also calculates the transfer delay in the bus from the CPU to IP-A, based on, for example, the data 402 of the RTL of the main bus and the data recorded in the user algorithm recorder 15. In the example in FIG. 5, “Characteristic 003” showing that the transfer delay in the bus from the CPU to IP-A is “Processing time C” is recorded.

Then, the second calculator 12 executes a simulation of the system (semiconductor integrated circuit) including each circuit component, based on the algorithm specified by the user, the processing time of each circuit component recorded in the characteristics DB501, and the high abstraction level model (step S103). Here, the second calculator 12 may use, as the high abstraction level model, for example, data that does not include data indicating the processing time in each circuit component, but data indicating the content of the processing to be executed in the circuit component (data of the operation level of the semiconductor integrated circuit). The high abstraction level model may be, for example, a block diagram model generated by a specific simulation tool. In this case, the block diagram model may be generated by an operation of connecting blocks representing each circuit component with lines on a graphical user interface. The high abstraction level model may be, for example, a code (program) automatically generated from the block diagram model. In this case, the code may be described with a specific programming language (e.g., an extended C language or SystemC language).

In the example of FIG. 6, by software 601 to 604 corresponding to each circuit component, the algorithm executed by the CPU of the semiconductor integrated circuit performs processing using IP-A, IP-B, and IP-C. In designing with the high abstraction level model, the amount of description can be reduced by designing at a high abstraction level of operation. Therefore, the productivity of design and verification can be improved. The data of the high abstraction level model may be previously stored in, for example, the internal storage device of the information processing apparatus 10 or an external storage device by the user of the information processing apparatus 10 or others.

In the processing in step S103, the second calculator 12 may totalize (add up, sum up) the processing time of each circuit component recorded in the characteristic DB501 at the time of execution of the processing of each circuit component in the simulation using the high abstraction level model. Then, the second calculator 12 may output information indicating the totalized processing time at the time of completion of the simulation using the high abstraction level model. This allows, for example, the user to recognize the processing time required when the algorithm executed by the CPU of the semiconductor integrated circuit is executed in an actual semiconductor integrated circuit. Thus, for example, the user of the information processing apparatus 10 can appropriately check whether or not the time required when a specific algorithm is executed by the CPU of the semiconductor integrated circuit satisfies a specific condition (requirement, constraint).

In this case, the second calculator 12 may record the processing time of the first circuit component recorded in the characteristic DB501 at the time of, for example, the processing of the first circuit component in the simulation using the high abstraction level model (for example, at the start or end of that processing), the processing time being added to a variable T for calculating the cumulative processing time. The initial value of the variable T may be 0. Then, the second calculator 12 may record the processing time of the second circuit component recorded in the characteristic DB501 at the time of, for example, the processing of the second circuit component in the simulation using the high abstraction level model, the processing time being added to the variable T.

Accordingly, for example, when a process using a specific IP core in the simulation using the high abstraction level model is executed by the CPU of a semiconductor integrated circuit, the required time T₁ for the process is calculated by the following formula (1).

T₁=L₁+L₂+L₃+L₄ (1)

Here, the term L₁ is the time required for the processing in the CPU of the semiconductor integrated circuit. The term L₂ is the transfer delay in the bus from the CPU to the IP core. The term L₃ is the time required for processing in the IP core. The term L₄ is the transfer delay in the bus from the IP core to the CPU. Each of the terms L₁, L₂, L₃, and L₄ is the processing time calculated by the first calculator 11 under use of the low abstraction level model. In this case, for example, in the example in FIG. 5, the term T₁ is the total value of processing time A, processing time C, processing time F, and processing time I in a case of the execution of the algorithm A in the CPU, the data transfer from the CPU to IP-A, the execution of the processing in the IP-A, and the transfer of the resulting processing data from the IP-A to the CPU.

The second calculator 12 may determine whether or not the time required when the specific algorithm is executed by the CPU of the semiconductor integrated circuit, the time being calculated based on the processing time of each circuit component, satisfies the specific condition. In this case, the information indicating the specific condition may be previously specified (set) by the user of the information processing apparatus 10.

In the SW First concept, the main focus is on the development of application software for large-scale systems including a plurality of LSIs. Therefore, in some cases, approaches are taken to simply model hardware and hardware control software at an upper level and to use the high abstraction level model to speed up the simulation as much as possible. In the high abstraction level model, the processing time of each circuit component is simplified or omitted. Accordingly, when a system with constraint based on the processing time of each circuit component is developed, the results of the simulation using the high abstraction level model may be inappropriate. For example, a system with constraint can be considered, the constraint showing that the total of the time required for processing of the specific algorithm in the CPU, the transfer delay in the bus from the CPU to IP-A, the time required for processing in IP-A, and the transfer delay in the bus from the IP-A to the CPU needs to be less than a specific time (e.g., a specific control cycle). In this case, if the simulation is logically correct, the simulation using the high abstraction level model results in the normal operation of the system regardless of whether or not the constraint is satisfied. However, if the constraint is not satisfied, the simulation using the low abstraction level model results in malfunction of the system.

For example, a case in which the high abstraction level model with short required time for the simulation is used in the upstream process of the design (development) while the low abstraction level model with high accuracy is used in the downstream process is considerable. This case has a risk of, for example, recognition of a characteristic problem at a stage of the development process or others using the low abstraction level model, which is later than the application software development process. On the other hand, by using the technique of the present disclosure, the characteristic problem in the related art only allowing the checking in the low speed simulation of the low abstraction level can be checked in the high speed simulation of the high abstraction level.

### Second Embodiment

In the first embodiment, the example of the simulation using the high abstraction level model after previously calculating the processing time has been described. In the second embodiment, an example of calculating the processing time at the time of processing using the processing time during the simulation performed using the high abstraction level model will be described. In the second embodiment, in some cases, for example, the processing load of the information processing apparatus 10 can be made less than that of the first embodiment.

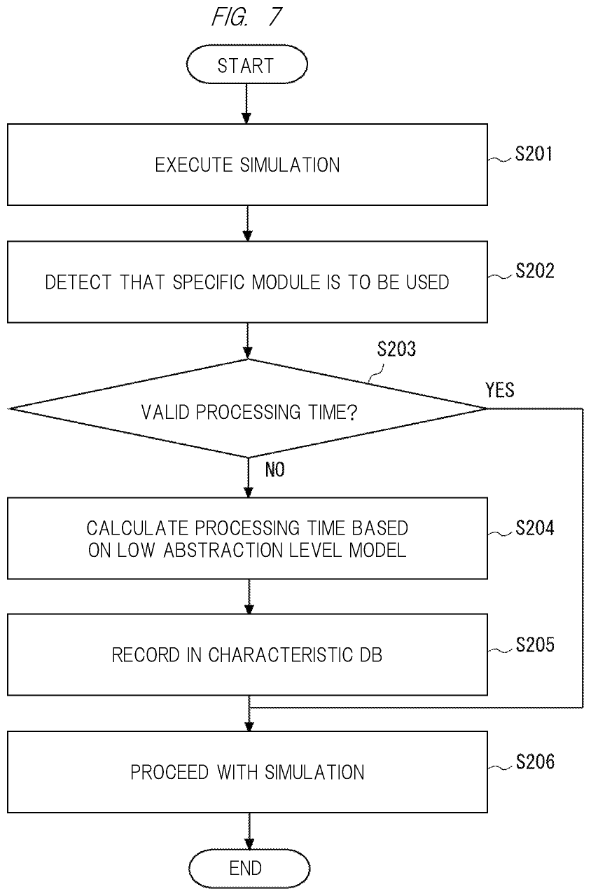

With reference to FIG. 7, the processing of the information processing apparatus 10 according to the present embodiment will be described. FIG. 7 is a flowchart showing an example of the processing of the information processing apparatus 10 of the present embodiment. The processes shown in FIG. 7 may be executed in response to, for example, an operation of the information processing apparatus 10 by the user.

In step S201, the second calculator 12 starts a simulation of a system (semiconductor integrated circuit) including each circuit component, based on the algorithm specified by the user and the high abstraction level model.

The second calculator 12 detects the processing using the specific circuit component in the executing simulation (step S202). Here, the second calculator 12 may detect, for example, the processing using any IP core (IP-A, IP-B, or IP-C) in the algorithm executed by the CPU of the semiconductor integrated circuit. In this case, the second calculator 12 may detect, for example, request of an API (Application Programming Interface) function for the high abstraction level model for any IP core in the algorithm executed by the CPU of the semiconductor integrated circuit.

Then, the second calculator 12 determines whether or not the processing time of the specific circuit component recorded in the characteristic DB501 is valid when the processing using the detected specific circuit component is performed (step S203). Here, the second calculator 12 may determine that the processing time of the specific circuit component is valid if the date and time at which the processing time of the specific circuit component has been calculated by the first calculator 11 is newer than date and time at which the low abstraction level model of the specific circuit component has been created. In this case, the first calculator 11 may cause the characteristic DB 501 to record the date and time at which the processing time of the specific circuit component has been calculated by the first calculator 11 in association with the characteristic ID. The date and time at which the low abstraction level model has been created may be recorded as, for example, metadata of a file of the circuit data of the RTL.

If the processing time of the specific circuit component is valid (YES in step S203), processing proceeds to step S206. On the other hand, if the processing time of the specific circuit component is not valid (NO in step S203), the first calculator 11 calculates the processing time of the specific circuit component, based on the low abstraction level model of the specific circuit component and the algorithm specified by the user (step S204).

Then, the first calculator 11 records the calculated processing time of the specific circuit component into the characteristic DB 501 (step S205). This allows the processing time of the specific circuit component to be updated appropriately even if, for example, design or specification of the specific circuit component is changed.

Then, the second calculator 12 proceeds with the simulation while using the processing time of the specific circuit component recorded in the characteristic DB501 (step S206). Here, based on the processing time of each circuit component, the second calculator 12 may adjust the time required for the processing of each circuit component in the simulation using the high abstraction level model as similar to the processing in step S103 in FIG. 3. The second calculator 12 may also calculate whether or not the time required for a specific algorithm to be executed by the CPU of the semiconductor integrated circuit and calculated based on the processing time of each circuit component satisfies a predetermined requirement (constraint).

In the foregoing, the invention made by the inventors of the present invention has been concretely described on the basis of the embodiments. However, it is needless to say that the present invention is not limited to the foregoing embodiments, and various modifications can be made within the scope of the present invention.

What is claimed is:

1. An information processing method executed in a computer, the method comprising the steps of:
based on a first abstraction level model corresponding to each of a plurality of circuit components included in a semiconductor integrated circuit, calculating a processing time of each of the circuit components; and
simulating processing of the semiconductor integrated circuit, based on the calculated processing time of each of the circuit components and a second abstraction level model having a higher level of abstraction than a level of the first abstraction level model.

2. The information processing method according to claim 1, further comprising, when processing using a specific circuit component is performed in an executing simulation, a step of calculating a processing time of the specific circuit component based on a low abstraction level model of the specific circuit component.

3. The information processing method according to claim 1,
wherein the processing time of each of the circuit components includes at least one of a time required for processing an algorithm in a CPU of the semiconductor integrated circuit, transfer delay in a bus from the CPU to the circuit component, a time required for processing of the circuit component, and transfer delay in a bus from the circuit component to the CPU.

4. The information processing method according to claim 3, further comprising, when processing using the circuit component is simulated, a step of determining whether or not a total value of the transfer delay in the bus from the CPU to the circuit component, the time required for processing of the circuit component, and a time corresponding to the transfer delay in the bus from the circuit component to the CPU satisfies a specific requirement.

5. The information processing method according to claim 1,
wherein the first abstraction level model is circuit data of a register transfer level described with a hardware description language, and
wherein the second abstraction level model is data indicating processing in each circuit component.

6. The information processing method according to claim 2, further comprising, when processing using a specific circuit component is performed in an executing simulation, if a processing time of the specific circuit component is not valid, a step of calculating the processing time of the specific circuit component.

7. The information processing method according to claim 6, further comprising a step of determining whether or not the processing time of the specific circuit component is valid, based on date and time at which the processing time of the specific circuit component has been calculated and date and time at which the low abstraction level model of the specific circuit component has been created.

8. An information processing apparatus comprising:
a first calculator configured to calculate, based on a first abstraction level model corresponding to each of a plurality of circuit components included in a semiconductor integrated circuit, a processing time of each of the circuit components; and
a second calculator configured to simulate processing of the semiconductor integrated circuit, based on the processing time of each of the circuit components calculated by the first calculator and a second abstraction level model having a higher level of abstraction than a level of the first abstraction level model.

9. A program causing a computer to:
based on a first abstraction level model corresponding to each of a plurality of circuit components included in a semiconductor integrated circuit, calculate a processing time of each of the circuit components; and
based on the calculated processing time of each of the circuit components and a second abstraction level model having a higher level of abstraction than a level of the first abstraction level model, simulate processing of the semiconductor integrated circuit.

10. A non-transitory computer readable medium storing a program causing a computer to:
based on a first abstraction level model corresponding to each of a plurality of circuit components included in a semiconductor integrated circuit, calculate a processing time of each of the circuit components; and
based on the calculated processing time of each of the circuit components and a second abstraction level model having a higher level of abstraction than a level of the first abstraction level model, simulate processing of the semiconductor integrated circuit.
